(19) United States
(12) Patent Application Publication
(10) Pub. No.: US 2002/0141004 A1
(43) Pub. Date: Oct. 3, 2002

(54) Image data correction device of an image reader

(76) Inventor: Eiichi Hayashi, Saitama-shi (JP)

Correspondence Address: Price, Heneveld, Cooper, DeWitt & Litton, 695 Kenmoor, S.E., Post Office Box 2567, Grand Rapids, MI, 49501, US

(21) Appl. No.: 10/106,632

(22) Filed: Mar. 26, 2002

(30) Foreign Application Priority Data
Mar. 30, 2001 (JP) 2001-102637

(51) Int. Cl. H04N 1/46; G03F 3/08

(52) U.S. Cl. 358/519; 358/505

(57) ABSTRACT

An image data correction device for an image reader has, in one embodiment, a white standard plate attached on a carriage of the image reader on which a light-source lamp is mounted such that standard data to be used as the standard of a correction to be made on image data is obtained with the movement of the light-source lamp. In other embodiments, a continuous or segmented white standard band is mounted to the platen glass along the direction of movement of the carriage.

### BACKGROUND OF THE INVENTION

1. Field of the Invention

The present invention relates to an image data correction device to be equipped in an image reader and particularly one which is capable of obtaining a constant amount of image data even though the intensity of light beams irradiated from the light-source lamp varies.

2. Description of the Related Art

An image reader such as a copying machine and a scanner is provided to read image data of an original on paper or the like to subject the image data to a various kinds of processing. Generally, the image reader is composed of a light-source lamp such as a fluorescent lamp for irradiating an original with light beams and a light receiving station including a photoelectric converter device such as CCD (Charge-Coupled Device). The reflected light beams from the original is incident on the light receiving station. In a stationary original type image reader, for example, an original is placed on a platen glass and is then irradiated with light beams from a light-source lamp being moved along the original. In addition, the optical path length from the original to a light receiving station should be kept at a constant even though the position for irradiating the original with light beams has changed. A reflector is also provided to guide reflected light beams to the light receiving station. In this type, furthermore, the reflector is designed to move along the original together with the light-source lamp.

In the above stationary original type image reader, furthermore, the obtained image data is corrected for more accurate acquisition of image data. For the correction, a judgment is made whether white (i.e., standard color) is obtained as the predetermined image data implies. If it is not, then the image data obtained from the original is corrected depending on the predetermined image data used in the judgment.

Heretofore, image data obtained from an image such as a test chart sheet has been used as a standard for such a correction. However, the correction cannot be performed properly when the image data obtained using the test chart sheet under the conditions in which the light-source lamp has deteriorated because of fatigue or the like. Therefore, a sufficient reproducibility may not be obtained at the time of regenerating or processing the image data obtained from the original by a copying machine, a personal computer, or the like.

For allowing the correction without the influence of deterioration of the light-source lamp, for example, several publications such as Japanese Patent Laid-Open Publication No. 8-184774 and 13-51364 disclose image forming apparatus and image readers capable of obtaining white-image data to be provided as standards prior to obtain the image data from originals. In each of such image readers, a white standard plate is provided as a standard of white color and is then arranged near a starting position of moving a light-source lamp. Subsequently, the image data with respect to this white standard plate is obtained prior to the acquisition of image data from the original, followed by calculating a correction value using the image data obtained from the white standard plate. The resulting correction value is applied on the data obtained from the original.

However, the conventional image reader has a disadvantage that the amount of light beams from the light-source lamp may be changed even at the time of moving the light-source lamp along the original. If the amount of light beams from the light-source has changed at the time of its movement, a sufficient correction may be failed at the time of correcting the image data thus obtained using a correction value on the basis of image data with respect to the white standard plate obtained before the movement.

### SUMMARY OF THE INVENTION

For solving the above disadvantages, an object of the present invention is to provide a correction device for correcting image data (hereinafter, also referred to as an image data correction device) in an image reader capable of always obtaining image data of white color to be used as a standard and sequentially making a correction to the image data every time the image data is obtained from an original.

As the technical means for attaining the above object, a first aspect of the present invention is to provide an image data correction device of an image reader to read an image formed on an original by irradiating the original placed on a platen glass with light beams from a light-source lamp while moving the light-source lamp, picking up reflected light beams from the original, followed by guiding the reflected light beams to a light receiving station, and to read the image formed on the original. The device comprises a white standard plate arranged along a direction of movement of the light-source lamp at a position where light beams from the light-source lamp is incident thereon and reflected therefrom and is then introduced to the light receiving station without interrupting the original from which the image data is to be obtained, to correct the image data obtained from the original based on standard data of the white standard plate.

According to the present invention, when the light-source lamp moves for obtaining image data from the original, the moving light-source lamp irradiates the white standard plate with light beams to obtain the standard data from the white standard plate. On the basis of the standard data, the correction can be performed on the image data obtained from the original. The correction can be made with obtaining the image data from the original. Therefore, even if there is a variation in the amount of light beams from the moving light-source lamp, any processing can be appropriately performed as the correction suitable for the intensity of light beams at that time. Also, in the image data correction device of the image reader, the white standard plate may be formed in the shape of a continuous band plate. According to such a configuration of the correction device, the correction can be made on the image data in succession as the data can be successively obtained from the white standard plate.

In addition, the white standard plate can be provided as a set of two or more white standard plates separated at an appropriate spacing.

When there is no need to successively obtain the standard data from the white standard plate according to the change in the amount of light beams from the light-source lamp, the standard data may be obtained at appropriate intervals and then the correction may be made depending on the obtained standard data.

A second aspect of the present invention is to provide an image data correction device of an image reader to read an image formed on an original by irradiating the original placed on a platen glass with light beams from a light-source lamp while moving the light-source lamp, picking up reflected light beams from the original, followed by guiding the reflected light beams to a light receiving station, and to read the image formed on the original. The device comprises a movable carriage on which the light-source lamp is mounted, and a white standard plate arranged on the carriage at a position where light beams from the light-source lamp is incident thereon and reflected therefrom and is then guided to the light receiving station without interrupting the original from which the image data is to be obtained, to correct the image data obtained from the original based on standard data of the white standard plate.

The white standard plate moves with the light-source lamp, so that corrections can be successively made on the image data as the standard data can be constantly obtained from the white standard plate. Furthermore, the correction can be made consistently without variation because the standard data can be constantly obtained from the same portion of the white standard plate in contrast of a continuous white standard plate or two or more white standard plates being arranged with an appropriate spacing in the moving direction of the light-source light beams. The white standard plate moves together with the light-source lamp, so that it can be minimized in size.

The white standard plate may be made of a ceramic material including a fluorescent substance. The white standard plate may preferably be made of a material that does not cause deformation or discoloration of the resulting plate under the influence of heat generated as a result of the continuous irradiation of light beams from the light-source lamp. A high reflectance of such a plate is also required.

These and other features, objects and advantages of the present invention will become apparent upon reading the following description thereof together with reference to the accompanying drawings.

### BRIEF DESCRIPTION OF THE DRAWINGS

FIG. 1 is a plan view of a full rate carriage integrated into an image reader having an image data correction device in accordance with the present invention;

FIG. 2(a) is a top plan view illustrating a white standard plate to be used in the image data correction device and a bracket for attaching the white standard plate to the full rate carriage in accordance with the present invention;

FIG. 2(b) is a bottom plan view of the white standard plate and the bracket;

FIG. 3 is a schematic side view illustrating the configuration of an image reader including the image data correction device in accordance with the present invention;

FIG. 4 is a top plan view of a platen glass, illustrating the configuration of the white standard plate as a continuous band-plate shape in accordance with another embodiment of the present invention;

FIG. 5 is a top plan view of the platen glass, for illustrating the configuration of a set of white standard plates arranged with a predetermined spacing in accordance with yet another embodiment of the present invention; and

FIG. 6 is a schematic perspective view illustrating the configuration of the image reader adapted to include the image data correction device of the present invention.

### DETAILED DESCRIPTION OF THE EMBODIMENTS

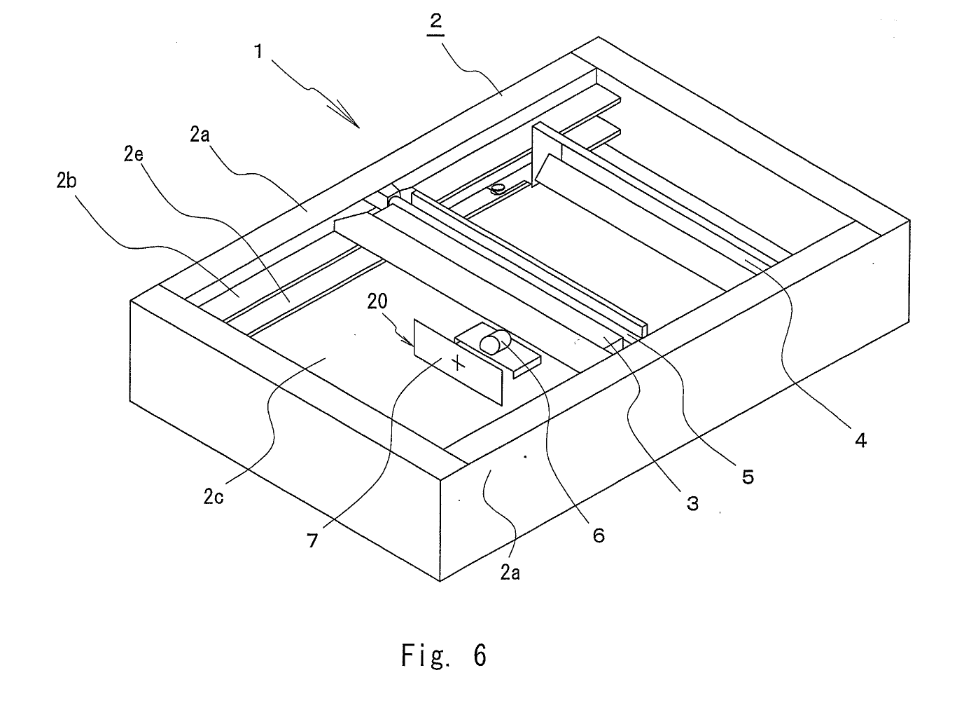

Referring first to FIG. 6, there is shown a perspective view schematically illustrating the configuration of an image reader 1 adapted to be equipped with an image data correction device in accordance with the present invention.

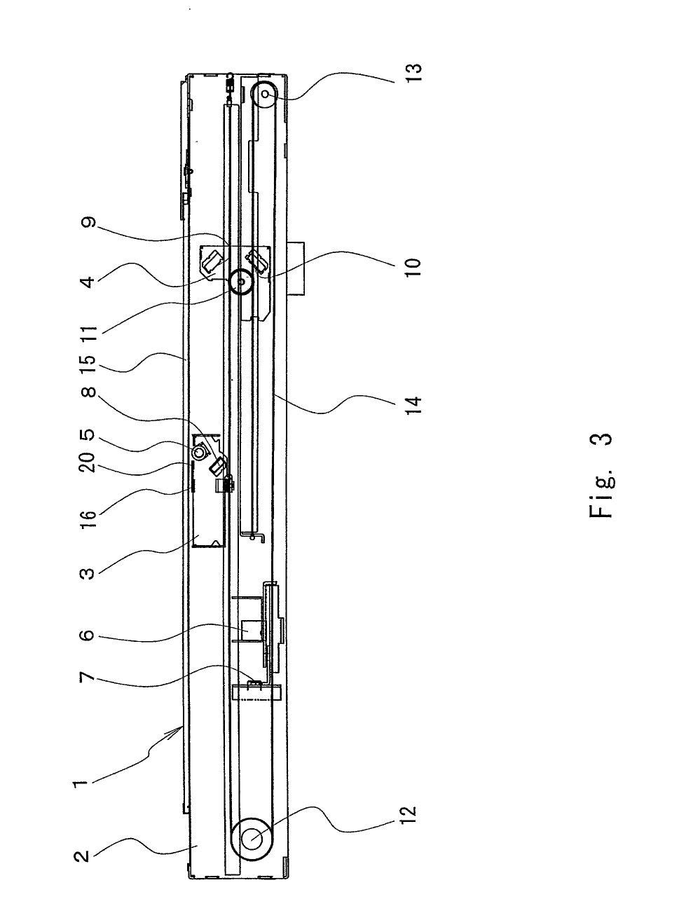

The image reader 1 includes a casing 2 having two guide plates 2b, 2e arranged in parallel on the inner sides of walls 2a longitudinal direction of the casing 2. As shown in the figure, a full rate carriage 3 is mounted on the guide plate 2b, while a half rate carriage 4 is mounted on the guide plate 2e. These carriages 3, 4 can be guided with their respective guide plates 2b, 2e to move longitudinal directions of the casing 2. In addition, there is a platen glass 15 (FIG. 3) attached on the top side of the casing 2. An original is to be placed on the platen glass 15. A light-source lamp 5 such as a fluorescent lamp is mounted on the full rate carriage 3 and is used to irradiate the original with light beams. Also, an image focusing lens 6 and a photoelectric converter device 7 such as a charge-coupled device are appropriately arranged on the bottom plate 2c of the casing 2.

As shown in FIG. 3, a first reflector 8 is arranged on the full rate carriage 3, while a second reflector 9 and a third reflector 10 are arranged on the half rate carriage 4. These reflectors 8, 9, 10 are arranged to form an optical path from the original to the photoelectric converter device 7 through the image focusing lens 6. The original reflects light beams from the light-source lamp 5, and then the light beams reflected from the original is incident on the photoelectric converter device 7 after being reflected by each of the first, second, and third reflectors 8, 9, 10 in sequence. In the case of acquiring image data on the original, the entire area of the original should be irradiated with light beams. Thus, the full rate carriage 3 is designed to be allowed to move over the entire area of the platen glass 15. In this case, the above optical path from the original to the photoelectric converter device 7 should be kept at a constant length even though the full rate carriage 3 moves. For this reason, the optical path can be kept at a constant length by synchronizing the movement of the half rate carriage 4 with that of the full rate carriage 3 under the conditions in which the movement of the half rate carriage 4 is set to almost half of the movement of the full rate carriage 3. Besides, these full rate and half rate carriages 3, 4 can be driven by a driving mechanism known in the art including a wire 14 routed over pulleys 11, 12, 13.

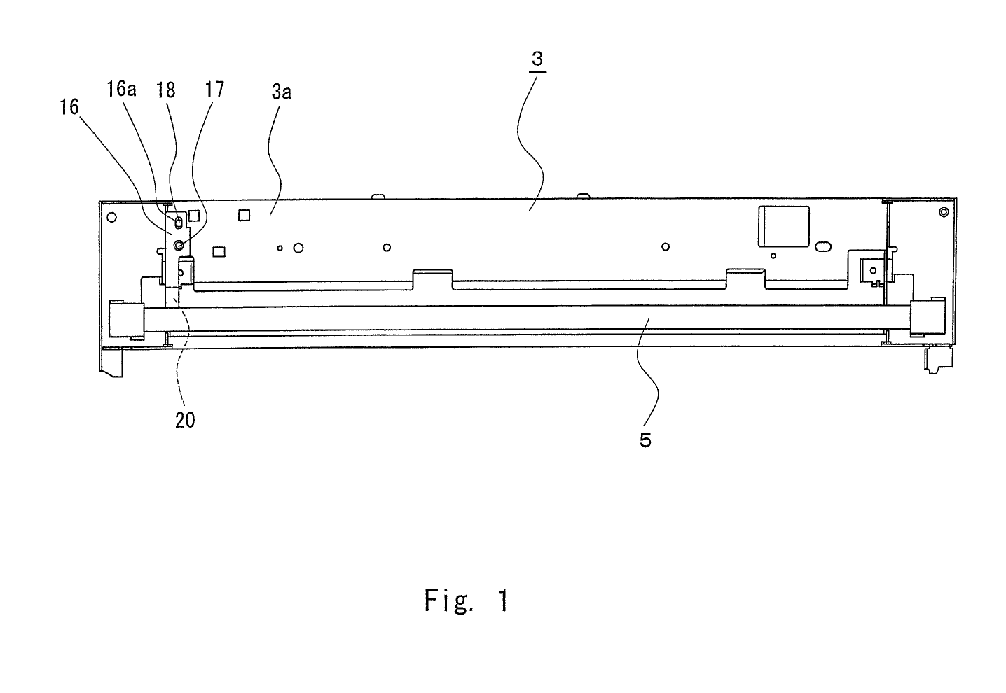

FIG. 1 is a schematic plan view of the full rate carriage 3 that includes a box-shaped frame 3a prepared by bending a plate material into an appropriate shape and then appropriately clamping it to form a box-shape. The light-source lamp 5 is built in the full rate carriage 3 such that the lamp 5 extends transverse to the direction of movement of the full rate carriage 3 and is placed on the end thereof on the half rate carriage-4's side. The irradiation range of the light-source lamp 5 is defined so as to obtain image data on the maximum-sized original by extending to the outside of the width of the maximum-sized original. Furthermore, a bracket 16 is fixed at its bottom end on an appropriate position on a frame 3a of the full rate carriage 3 through a set screw 17. A positioning pin 18 is embodied in the frame 3a. The bracket 16 can be positioned in place by fitting the positioning pin 18 into an elongated hole 16a formed in the bracket 16.

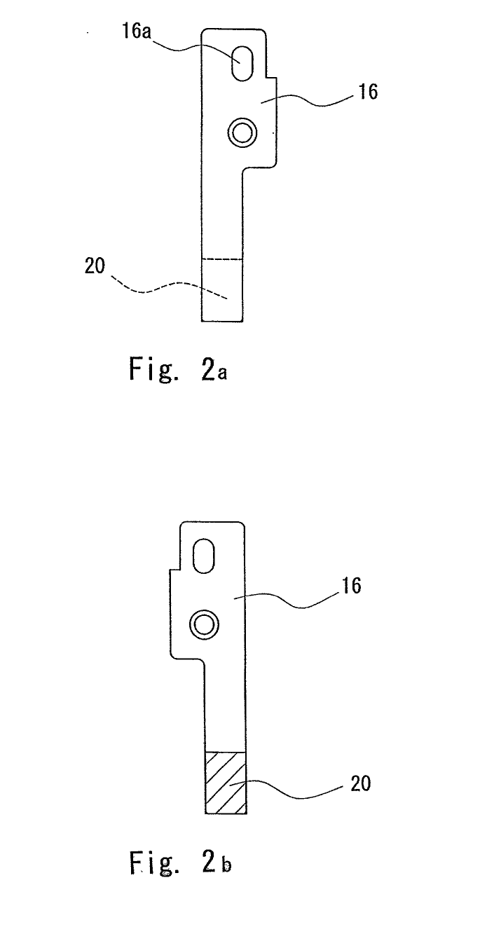

As shown in FIG. 2(b), there is a white standard plate 20 is attached on the tip of the bracket 16 on the lamp's side. The white standard plate 20 is located at a position where the plate 20 can be irradiated with light beams from the light-source lamp 5 such that it reflects the light beams to the first reflector 8. Furthermore, the white standard plate is located at such a position facing to the end of the light-source lamp 5 to avoid the light beams of the light-source lamp 5 incident on the original from being interrupted by the plate.

The white standard plate 20 receives light beams from the light-source lamp 5 when the light-source lamp 5 is turned, so that the white standard plate 20 can be heated. As a result, the white standard plate 20 may be preferably prepared from a material hardly deformed or discolored (e.g., faded out) by the application of heat. For example, the material may be a ceramic material including a fluorescent material. Hereinafter, the action of the above image data correction device will be described as one of preferred embodiments of the present invention.

An original from which the desired image data is to be read is placed on the platen glass 15. Then, the image reader 1 is actuated. The full rate carriage 3 and the half rate carriage 4 move along the original to irradiate the original with light beams from the light-source lamp 5 on the full rate carriage 3. In addition, the white standard plate 20 also moves with the full rate carriage 3 and is irradiated with light beams from the light-source lamp 5. The light beams reflected from the white standard plate 20 and the light beams reflected from the original are then incident on the photoelectric converter device 7 after being reflected by each of the first, second, and third reflectors 8, 9, 10 in sequence and passing through the image focusing lens 6. As a result, the standard data of the white standard plate 20 and the image data of the original can be obtained. While keeping watch on the standard data obtained from the reflected light beams from the white standard plate 20, a collection value to be applied on the image data is calculated and then the correction is made on the image data. Therefore, if the amount of light beams from the light-source lamp 5 changes during the movement of the lamp 5, the image data can be corrected depending on such a change. As a result, appropriate image data can be obtained.

The configuration of the image data correction device described above is taken as an illustration of one of the preferred embodiments of the present invention. While the present invention is not limited to such a configuration, many modifications and changes may be effected by those skilled in the art. For example, in the present invention, the white standard plate 20 is attached on the full rate carriage 3 such that the white standard plate 20 moves together with the full rate carriage 3. Alternatively, the white standard plate in the shape of a band-plate may be provided on the top plate of the casing 2 or the back of the platen glass 15 in the moving direction of the full rate carriage 3.

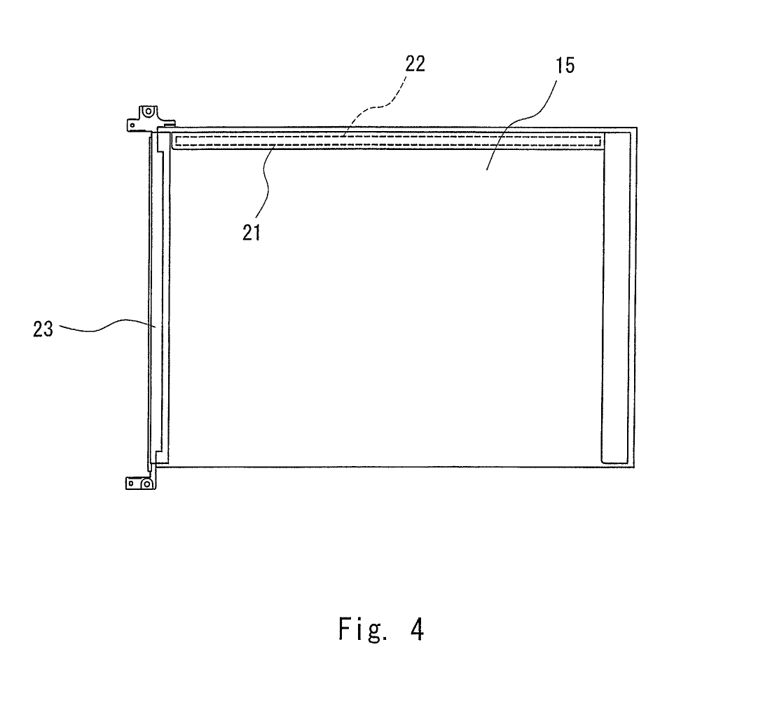

FIG. 4 is a plan view of the platen glass 15. A guide plate 21 for positioning an original on the platen glass 15 is adhered on the original placing surface of the platen glass 15 such that the guide plate 21 extends along the moving direction of the light-source lamp 5. In the case of having such a structure, the white standard plate 22 in the shape of a band-plate may be adhered on the back of the platen glass 15 corresponding to the guide plate 21. In addition, a glass-supporting plate 23 is attached on one end of the platen glass 15 to fix the platen glass 15 on the casing 2.

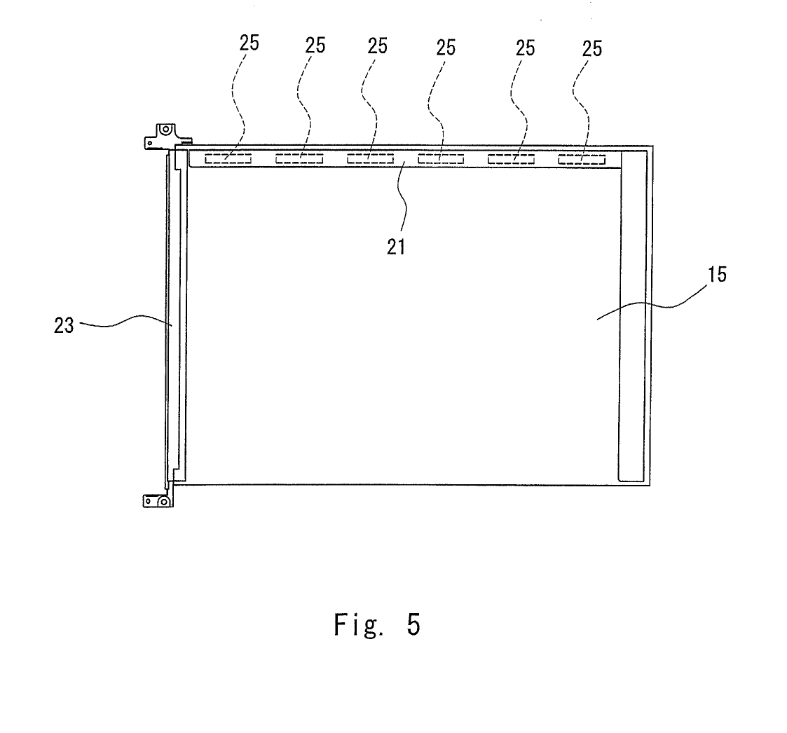

Instead of the white standard plate in the shape of a band plate, as shown in FIG. 5, an alternative white standard plate may be a set of two or more spaced-apart white standard plates 25 with an appropriate shape. These white standard plates 25 are arranged in a row with a predetermined spacing between adjacent plates 25 and adhered on the back of the platen glass 15 corresponding to the guide plate 21. The above preferred embodiments shown in FIG. 4 and FIG. 5 has been explained as those having white standard plates 22, 25 adhered on the predetermined position on the back of the platen glass 15 corresponding to the guide plate 21. Alternatively, the surface of the guide plate 21 itself, which is on the side of the platen glass 15, may be used as a white standard plate. Furthermore, an adhesive for adhering the guide plate 21 on the platen glass 15 may be mixed with white pigments so as to provide the adhesive with the function of a white standard plate.

While the white standard plates in the above embodiments have been prepared from a ceramic material including a fluorescent material, any of other inexpensive materials hardly affected with heat and hardly deformed and discolored may be preferably used.

As described above, according to the image data correction device of the image reader of the invention, the correction is made on the image data in synchronization with the acquisition of image data with the movement of the light-source lamp. Therefore, the image data appropriately processed can be obtained. In other words, for example, an image reproduced by a copying machine or a personal computer can be reproduced substantially with precision.

According to the image data correction device of the image reader in which the white standard plate is provided as a continuous band-plate, the standard data can be sequentially obtained and the correction can be made on the image data every time it is obtained.

Moreover, according to the image data correction device of the image reader in which the white standard plate is provided as a set of two or more white standard plates separated by appropriate spaces, the standard data can be obtained enough to correct the image data. In addition, if one of the white standard plates becomes deteriorated, it can be replaced with new one. Therefore, the exchange work becomes easy, and it can be performed at lower cost compared with the exchange work for the white standard plate in the shape of a continuous band-plate.

In addition, the white standard plate is arranged on the movable carriage, where the light-source lamp is mounted, on a position where light beams from the light-source lamp is incident thereon and the light beams can be then reflected therefrom to the light receiving station without interrupting the original from which the image data is to be obtained. Then, image data obtained from the original is corrected based on the standard data of the white standard plate. Thus, the image data correction device of the image reader can obtain the standard data constantly from the same portion of the white standard plate, thereby making a uniform correction on the image data. In addition, the white standard plate can be minimized in size, allowing easy exchange work should the white standard plate become deteriorated, thus allowing a reduction in cost.

Furthermore, according to the image data correction device of the image reader in which the white standard substrate is made of a ceramic material including a fluorescent material, the white standard substrate shows a high reflectance and is hardly deformed, discolored, and deteriorated, in spite of being subjected to heat from the light-source lamp. Therefore, the standard data can be accurately obtained.

It will become apparent to those skilled in the art that various modifications to the preferred embodiment of the invention as described herein can be made without departing from the spirit or scope of the invention as defined by the appended claims.

What is claimed is:

1. An image data correction device of an image reader to read an image formed on an original by irradiating the original placed on a platen glass with light beams from a light-source lamp on a carriage while moving the light-source lamp, picking up reflected light beams from the original, followed by introducing the reflected light beams to a light receiving station, and to read the image formed on the original, comprising:
a white standard member positioned along the direction of movement of the light-source lamp at a position where light beams from the light-source lamp are incident thereon and reflected therefrom and are then guided to the light receiving station without interrupting the original from which the image data is to be obtained to correct the image data obtained from the original based on standard data of the white standard member.

2. The image data correction device as defined in claim 1 wherein said white standard member comprises a plate mounted to the carriage.

3. The image data correction device as defined in claim 1, wherein the white standard member is formed in a shape of a continuous band plate.

4. The image data correction device as defined in claim 1, wherein the white standard member is provided as a set of two or more white standard plates separated at an appropriate spacing.

5. The image data correction device of an image reader to read an image formed on an original by irradiating the original placed on a platen glass with light beams from a light-source lamp while moving the light-source lamp, picking up reflected light beams from the original, followed by guiding the reflected light beams to a light receiving station, and to read the image formed on the original, the device comprising a movable carriage on which the light-source lamp is mounted, and a white standard plate arranged on the carriage on a position where light beams from the light-source lamp is incident thereon and reflected therefrom and is then guided to the light receiving station without interrupting the original from which the image data is to be obtained, to correct the image data obtained from the original based on standard data of the white standard plate.

6. The image data correction device as defined in claim 1, wherein the white standard member is made of a ceramic material including a fluorescent material.

7. The image data correction device as defined in claim 2, wherein the white standard member is made of a ceramic material including a fluorescent material.

8. The image data correction device as defined in claim 3, wherein the white standard member is made of a ceramic material including a fluorescent material.

9. The image data correction device as defined in claim 4, wherein the white standard member is made of a ceramic material including a fluorescent material.

10. The image data correction device as defined in claim 5, wherein the white standard member is made of a ceramic material including a fluorescent material.

11. An image data correction device of an image reader to read an image formed on an original by irradiating the original placed on a platen glass with light beams from a light-source lamp while moving the light-source lamp, picking up reflected light beams from the original, followed by introducing the reflected light beams to a light receiving station, and to read the image formed on the original, the device comprising:
a white standard plate arranged along a direction of movement of the light-source lamp on a position where light beams from the light-source lamp are incident thereon and reflected therefrom and are then guided to the light receiving station without interrupting the original from which the image data is to be obtained to correct the image data obtained from the original based on standard data of the white standard plate.

12. The image data correction device as defined in claim 11, wherein the white standard plate is formed in the shape of a continuous band plate.

13. The image data correction device as defined in claim 11, wherein the white standard plate is provided as a set of two or more white standard plates separated at an appropriate spacing.

14. The image data correction device as defined in claim 11, wherein the white standard plate is made of a ceramic material including a fluorescent material.

15. The image data correction device as defined in claim 12, wherein the white standard plate is made of a ceramic material including a fluorescent material.

16. The image data correction device as defined in claim 13, wherein the white standard plate is made of a ceramic material including a fluorescent material.
